(19) United States
(12) Patent Application Publication
(10) Pub. No.: US 2015/0194462 A1
(43) Pub. Date: Jul. 9, 2015

(54) METHOD OF MANUFACTURING SOLID-STATE IMAGE SENSOR

(71) Applicant: CANON KABUSHIKI KAISHA, Tokyo (JP)

(72) Inventors: Nobutaka Ukigaya, Yokohama-shi (JP); Koji Hara, Ichikawa-shi (JP)

(21) Appl. No.: 14/570,164

(22) Filed: Dec. 15, 2014

(30) Foreign Application Priority Data
Jan. 8, 2014 (JP) 2014-001953

(51) Int. Cl. H01L 27/146; H01L 21/3115; H01L 21/469

(52) U.S. Cl. CPC H01L 27/14687; H01L 21/469; H01L 21/31155

(57) ABSTRACT

A method of manufacturing a solid-state image sensor includes forming a resist film with a thickness of not less than 7 μm on a semiconductor substrate including an active region and an element isolation region, forming a resist pattern including an opening by performing a photolithography process on the resist film, and implanting ions into a pixel array region on the semiconductor substrate through the opening, wherein the opening of the resist pattern includes a corner portion, and the corner portion is positioned not above the element isolation region but above the active region.

### BACKGROUND OF THE INVENTION

1. Field of the Invention

The present invention relates to a method of manufacturing a solid-state image sensor.

2. Description of the Related Art

As one of approaches for increasing the sensitivity of a solid-state image sensor, there is an approach of forming a depletion layer even in a deep position in a semiconductor substrate. In this approach, it is necessary to implant ions into the semiconductor substrate with energy of over 1 MeV. Furthermore, in order to implant the ions selectively into a limited region of the semiconductor substrate, an ion implantation mask is required to have a sufficient ion blocking ability in ion implantation with high energy.

Japanese Patent Laid-Open No. 2002-217123 describes a method of forming the first inorganic film, a silicon layer, and the second inorganic film in order on the surface of a silicon substrate, patterning the second inorganic film, and patterning the silicon layer using the patterned second inorganic film as a mask. In this method, ions are implanted into the silicon substrate via the first inorganic film using the patterned silicon layer as a mask. In this method, however, the process for forming an ion implantation mask is complex, resulting in a decrease in manufacturing efficiency.

### SUMMARY OF THE INVENTION

The present invention provides a technique advantageous in simplifying a process.

One of aspects of the present invention provides a method of manufacturing a solid-state image sensor, comprising steps of: forming a resist film with a thickness of not less than 7 μm on a semiconductor substrate including an active region and an element isolation region; forming a resist pattern including an opening by performing a photolithography process on the resist film; and implanting ions into a pixel array region on the semiconductor substrate through the opening, wherein the opening of the resist pattern includes a corner portion, and the corner portion is positioned not above the element isolation region but above the active region.

Further features of the present invention will become apparent from the following description of exemplary embodiments with reference to the attached drawings.

### BRIEF DESCRIPTION OF THE DRAWINGS

FIGS. 1A and 1B are schematic views showing a semiconductor substrate on which a plurality of solid-state image sensors being manufactured are arrayed, and one solid-state image sensor being manufactured and an alignment mark region arranged in its peripheral portion;

FIGS. 2A and 2B are schematic views each showing the section of the solid-state image sensor being manufactured;

FIGS. 3A and 3B are schematic views each showing the section of the solid-state image sensor being manufactured;

FIGS. 4A and 4B are schematic views each showing the section of the solid-state image sensor being manufactured;

FIGS. 5A and 5B are schematic views each showing the section of the solid-state image sensor being manufactured;

FIGS. 6A and 6B are schematic views each showing the section of the solid-state image sensor being manufactured;

FIGS. 7A and 7B are schematic views each showing the section of the solid-state image sensor being manufactured;

FIGS. 8A and 8B are schematic views each showing the section of the solid-state image sensor being manufactured;

FIG. 9 is a schematic view showing the section of the solid-state image sensor being manufactured;

FIGS. 10A and 10B are views each showing a modification of a resist pattern;

FIGS. 11A and 11B are views each showing a modification of a resist pattern; and

FIG. 12 is a view showing a modification of the resist pattern.

### DESCRIPTION OF THE EMBODIMENTS

An exemplary embodiment of the present invention will be described below with reference to the accompanying drawings.

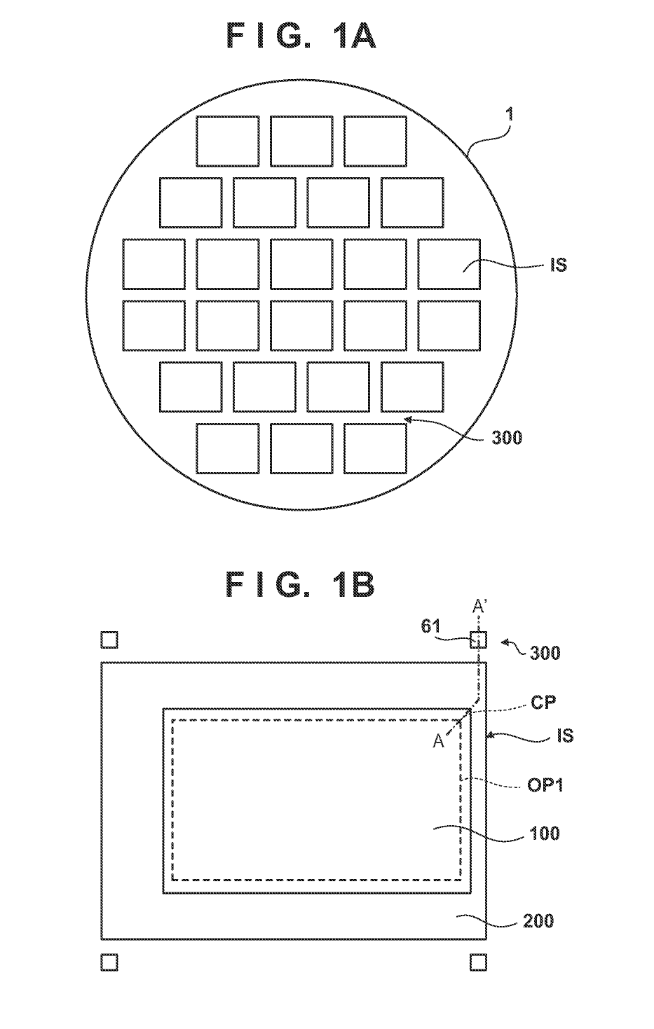

FIG. 1A schematically shows a semiconductor substrate 1 on which a plurality of solid-state image sensors IS being manufactured are arrayed. FIG. 1B schematically shows one solid-state image sensor IS being manufactured and an alignment mark region 61 arranged in its peripheral portion. Each solid-state image sensor IS includes a pixel array region 100 including a plurality of pixels and a peripheral region 200 arranged outside the pixel array region 100. When each solid-state image sensor IS is formed as a MOS image sensor, each pixel can include, for example, a photoelectric conversion unit, a transfer transistor, a charge-voltage conversion unit, a reset unit, an output unit, and a selection unit. However, each solid-stage image sensor IS may be formed as another form of image sensor such as a CCD image sensor. The peripheral region 200 can include, for example, a vertical scanning circuit, a constant current source block, a column amplifier block, a holding capacitor block, a horizontal scanning circuit, and an output amplifier block.

The pixel array region 100 and the peripheral region 200 of each solid-state image sensor IS are defined on the semiconductor substrate 1. In a plurality of photolithography processes of manufacturing the solid-state image sensors IS, an alignment mark is formed in the alignment mark region 61. The alignment mark region 61 can be arranged in, for example, a scribe line 300 for isolating the plurality of solid-state image sensors IS from each other. On a certain side face, the semiconductor substrate 1 is understood as including an effective region and a non-effective region. The solid-state image sensors IS are arranged in the effective region, and the alignment mark region 61 is arranged in the non-effective region. The scribe line 300 can also be arranged in the non-effective region.

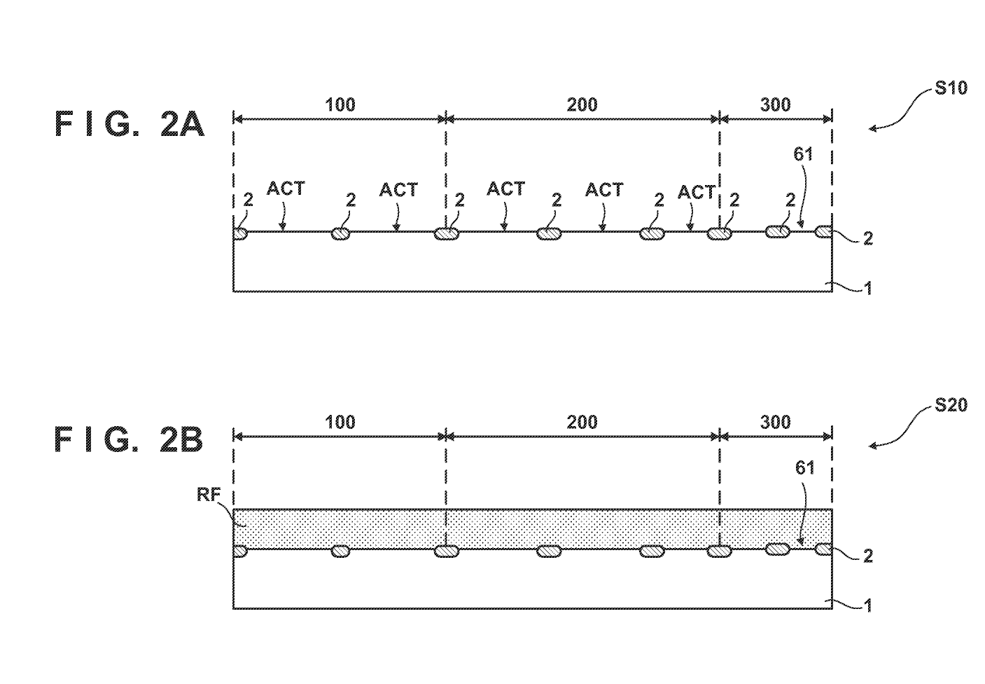

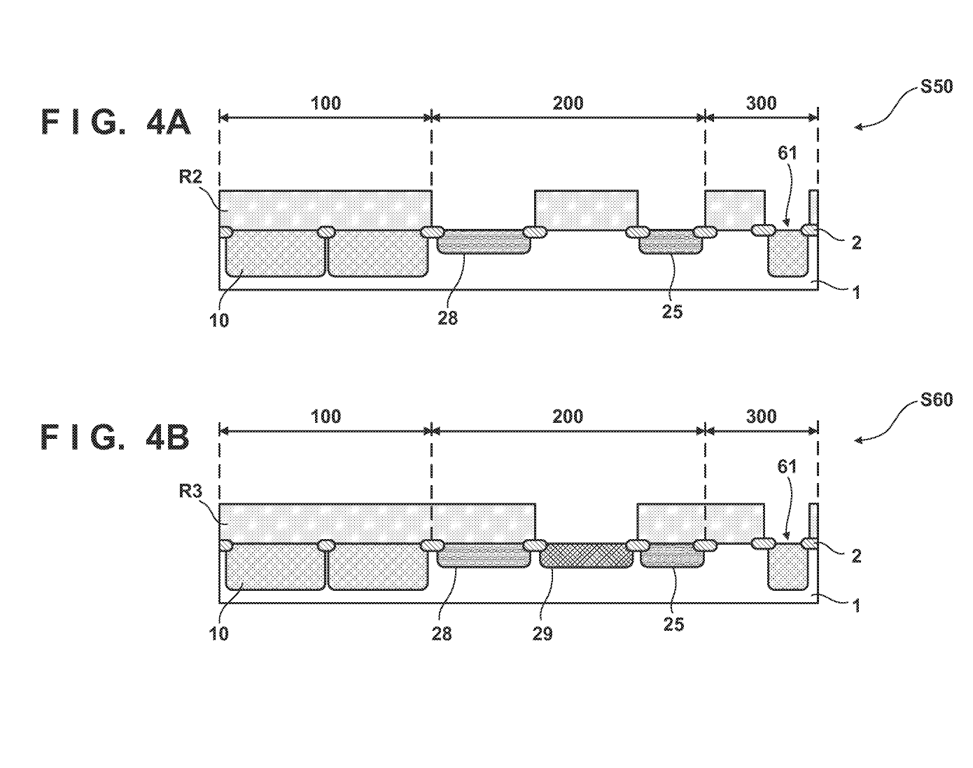

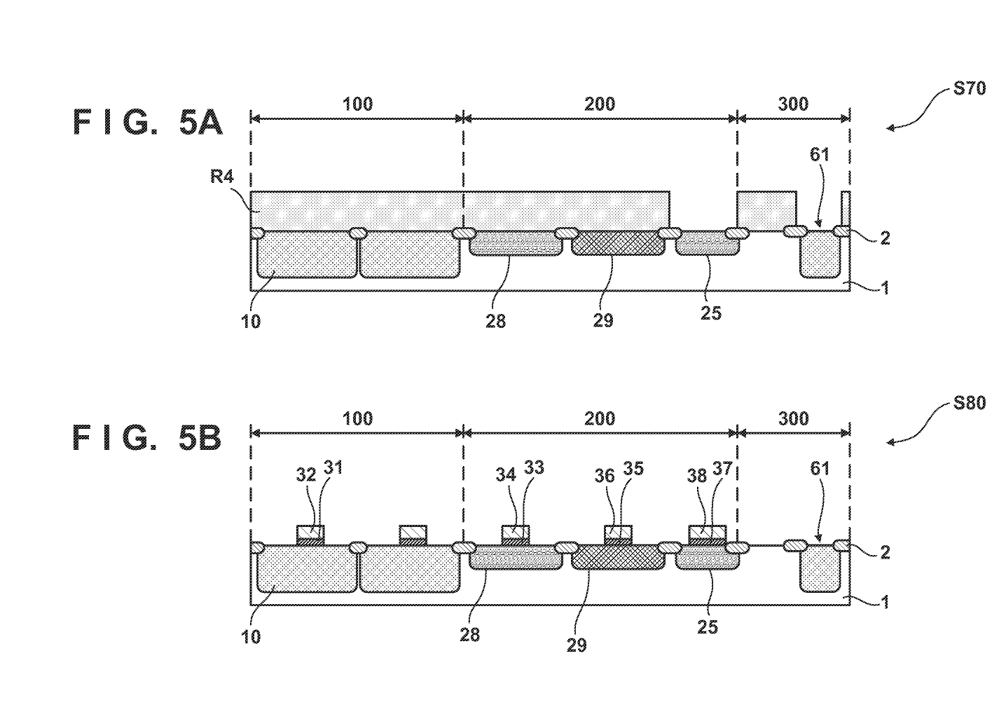

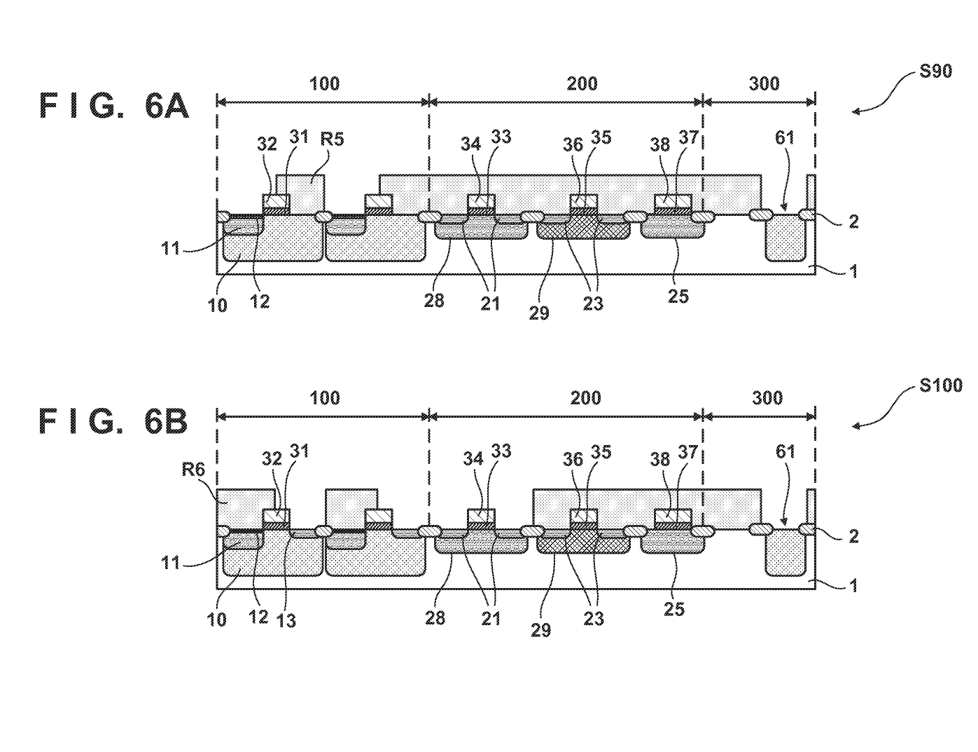

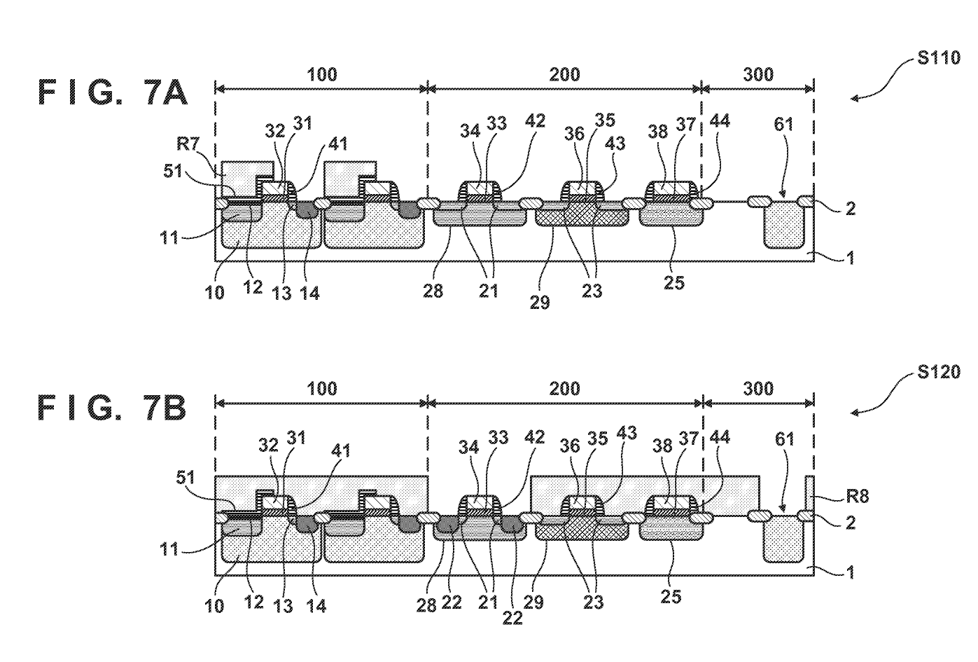

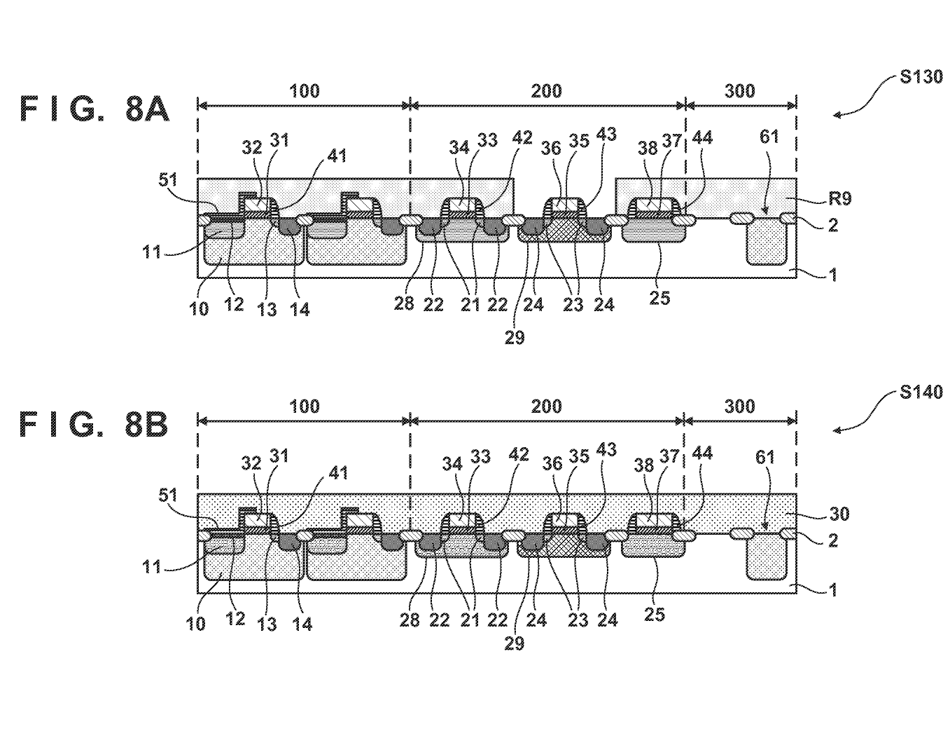

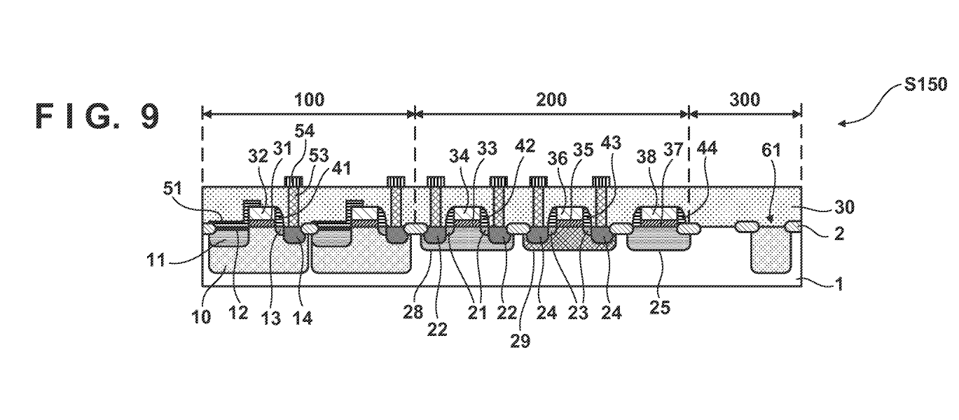

FIGS. 2A to 9 schematically show the section of the solid-state image sensor IS being manufactured, taken along an A-A′ line in FIG. 1B. A method of manufacturing the solid-state image sensor IS will exemplarily be described below with reference to FIGS. 2A to 9. The semiconductor substrate 1 includes active regions ACT and element isolation regions 2. Each active region ACT is defined in a region where no element isolation region 2 exists. The pixel array region 100 includes the active region ACT and the element isolation region 2, and the peripheral region 200 also includes the active region ACT and the element isolation region 2. The element isolation region 2 can be, for example, a LOCOS element isolation region or an STI element isolation region. The element isolation region 2 has a function of isolating a plurality of semiconductor regions from each other. The semiconductor regions isolated from each other can be, for example, the semiconductor region where the photoelectric conversion unit is formed, and the semiconductor region where the source or drain of a transistor or a capacitor is formed.

In step S10, the semiconductor substrate 1 including the active region ACT and the element isolation region 2 is prepared. The active region ACT and the element isolation region 2 are complementary to each other. In an example shown in FIG. 2A, each of the pixel array region 100, the peripheral region 200, and the scribe line 300 includes the active region ACT and the element isolation region 2.

In steps S20 and S30, a resist pattern R1 for implanting ions with, for example, an ultrahigh energy of 6 MeV is formed. First, in step S20, a resist film RF is formed on the semiconductor substrate 1 including the active region ACT and the element isolation region 2. The resist film RF can typically be formed by coating the semiconductor substrate 1 with a resist material by spin coating. The resist film RF can have a thickness of 7 μm or more.

In step S30, the resist pattern R1 having an opening OP1 is formed by performing the photolithography process for the resist film. The resist pattern R1 can include a pattern for forming an alignment mark in the alignment mark region 61. Note that in FIGS. 2A to 9, the pattern for forming the alignment mark that can be provided in each resist pattern is shown as one opening for simplification.

In one example, ZR8800 (manufactured by Tokyo Ohka) is used as a material for the resist film RF, and the thickness of the resist film RF is set to 9 μm. A lithography step includes coating, exposure, and development of the resist film, and burning (post-bake). Burning can be performed, for example, at 120° C. for 120 sec. Burning can expand the dimension of the opening.

The present inventor has found that a crack occurs in the obtained resist pattern R1 in design in which a corner portion CP of the opening OP1 obtained after the lithography step is positioned above the element isolation region 2. This crack is conspicuous especially when the thickness of the resist film RF is 7 μm or more. Based on this finding, the present inventor has found that crack occurrence can be reduced by forming the resist pattern R1 such that the corner portion CP of the opening OP1 obtained after the lithography step is positioned not above the element isolation region 2 but above the active region ACT. This is because the corner portion CP receives a smaller stress when arranged above the active region ACT as compared to the case in which the corner portion CP is arranged above the element isolation region 2. Based on the above-described findings, in step S30, the resist pattern R1 is formed such that the corner portion CP of the opening OP1 is positioned not above the element isolation region 2 but above the active region ACT. When the resist pattern R1 includes the opening and the pattern in the alignment mark region 61, the corner portion is arranged not above the element isolation region 2 but above the active region ACT.

According to this embodiment, the crack occurrence is reduced while keeping a thick resist pattern. This eliminates a need to form a film (such as a silicon film or a silicon nitride film) other than the resist film as a mask. Therefore, it is possible to simplify a process for forming an ion implantation mask.

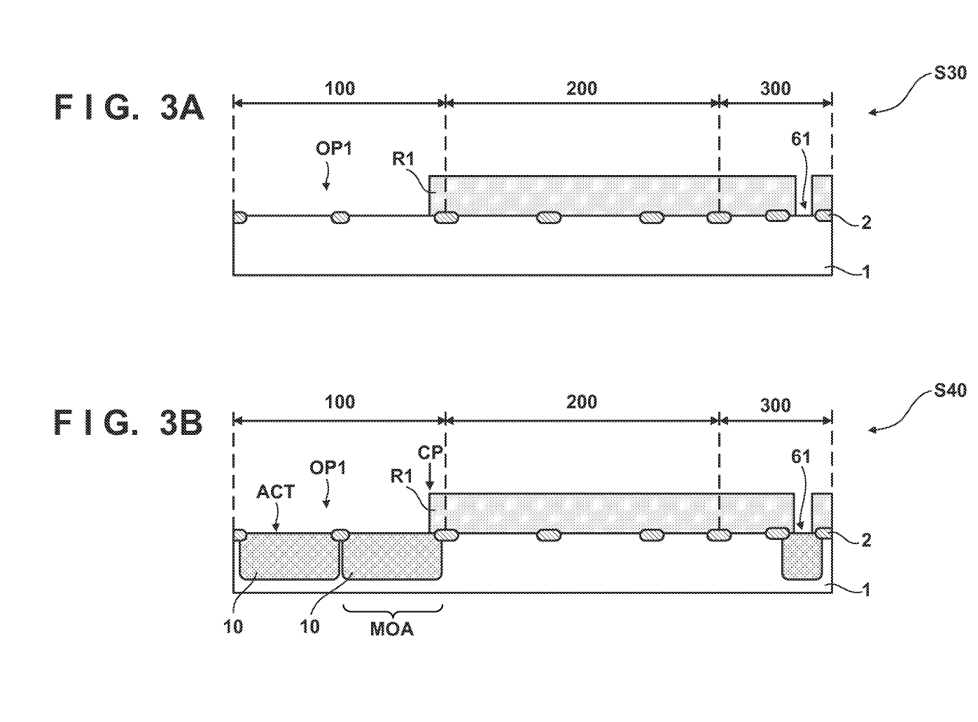

In examples shown in FIGS. 3A and 3B, the corner portion CP is arranged above the active region ACT in the pixel array region 100. More specifically, the active region ACT includes an outermost active region MOA for, out of a plurality of pixels forming the pixel array region 100, a pixel arranged at an outermost portion in the pixel array region 100, and the corner portion CP is arranged in the outermost active region MOA.

In step S40, ions (boron (B)) are implanted into the semiconductor substrate 1 with, for example, an ultrahigh energy of 6 MeV through the first opening OP1 of the resist pattern R1. In examples shown in FIGS. 2A to 9, the resist pattern R1 has one common opening OP1 to the plurality of pixels in one pixel array region 100. When the semiconductor substrate 1 includes N regions of the solid-state image sensors IS, the resist pattern R1 has N openings OP1 for N pixel array regions 100. By performing step S40, a well (first semiconductor region) 10 is formed in the pixel array region 100.

In steps S50, S60, and S70, resist patterns R2, R3, and R4 are formed, and ions are implanted into the semiconductor substrate 1 through the resist patterns R2, R3, and R4. This forms diffusion layers (the source and drain) 28 of each of an NMOS transistor and a PMOS transistor in the peripheral region 200, and a diffusion layer (lower electrode) 25 for the holding capacitor of the holding capacitor block in the peripheral region. The thickness of each of the resist patterns R2, R3, and R4 is, for example, about 1 μm, and no crack is produced.

In step S80, an insulating film and a polysilicon film are formed in order on the semiconductor substrate 1, and patterned. By doing so, a gate structure including a gate insulating film 31 and a gate electrode 32 is formed in the pixel array region 100 (the gate structure of the transfer transistor is shown). In the peripheral region 200, while a gate electrode including a gate insulating film 33 and a gate electrode 34 is formed in the region of the NMOS transistor, a gate electrode including a gate insulating film 35 and a gate electrode 36 is formed in the region of the PMOS transistor. Furthermore, a structure including an insulating film 37 and an upper electrode 38 is formed in the region of the holding capacitor in the peripheral region 200.

In step S90, a resist pattern (second resist pattern) R5 having a plurality of openings corresponding to the respective charge accumulation regions 11 of the plurality of pixels. An impurity (here, arsenic (As)) of the first conductivity type (here, an n type) is implanted into the semiconductor substrate 1 using the resist pattern R5 and the gate electrode 32 as masks. This forms the charge accumulation region (second semiconductor region) 11 made of a semiconductor region of the first conductivity type. The maximum depth of the charge accumulation region 11 is smaller than that of the well 10. In step S90, an impurity (here, boron (B)) of the second conductivity type (here, a p type) is implanted in the vicinity of the surface of the semiconductor substrate 1 using the resist pattern R5 and the gate electrode 32 as masks. This forms a protective region 12 on the charge accumulation region 11. The protective region 12 of the second conductivity type, the charge accumulation region 11 of the first conductivity type, and the well 10 of the second conductivity type form a buried photoelectric conversion unit.

In step S100, a resist pattern R6 is formed, and the impurity of the first conductivity type is implanted into the semiconductor substrate 1 at a low concentration using the resist pattern R6 and the gate electrodes 32 and 34 as masks. This forms a lightly doped region 13 of the charge-voltage conversion unit (floating diffusion) in the pixel array region 100 and an LDD region 21 of the NMOS transistor in the peripheral region 200.

In step S110, a two-layer insulating film is formed to cover the gate electrodes 32, 34, and 36 and the upper electrode 38. Out of the two-layer insulating film, the first-layer insulating film is formed by, for example, a silicon nitride film (SiN). The first-layer insulating film preferably has a film thickness of 40 nm to 55 nm, considering that it is made to function as an antireflection film which prevents light reflection on the light receiving surface of the photoelectric conversion unit (protective region 12). Then, the second-layer insulating film is formed to cover the first-layer insulating film. The second insulating film can be formed by, for example, a silicon oxide film (SiO₂).

In step S110, a resist pattern R7 covering the protective region 12 is further formed on the two-layer insulating film. Then, etching is performed using the resist pattern R7 as a mask. This forms a side wall spacer 41 on the side faces of the gate electrode 32 and the gate insulating film 31 on the side of the charge-voltage conversion unit as well as an insulating film 51 which covers the protective region 12 and the side faces of the gate electrode 32 and the gate insulating film 31 on the side of the protective region 12. Moreover, side wall spacers 42, 43, and 44 are also formed on the side face of the gate electrode 34 and the gate insulating film 33, the side face of the gate electrode 36 and the gate insulating film 35, and the side face of the upper electrode 38 and the insulating film 37, respectively. After that, the resist pattern R7 is removed.

In step S120, a resist pattern R8 having an opening in the region of the NMOS transistor is formed, and ions of the first conductivity type are implanted into the semiconductor substrate 1 at a high concentration using the resist pattern R8, the gate electrode 34, and the side wall spacer 42 as masks. This forms the source and drain 22 of the NMOS transistor.

In step S130, a resist pattern R9 having an opening in the region of the PMOS transistor is formed, and ions of the second conductivity type are implanted into the semiconductor substrate 1 at the high concentration using the resist pattern R9, the gate electrode 36, and the side wall spacer 43 as masks. This forms the source and drain 24 of the PMOS transistor.

In step S140, an interlayer insulating film 30 is formed on the semiconductor substrate 1. In step S150, a contact hole is formed in the interlayer insulating film 30, a contact plug 53 is formed in that contact hole, and an interconnection pattern 54 is further formed on the interlayer insulating film 30. Although not shown below, the interlayer insulating film and the interconnection pattern are further stacked, and then a color filter, a microlens, and the like are formed on them.

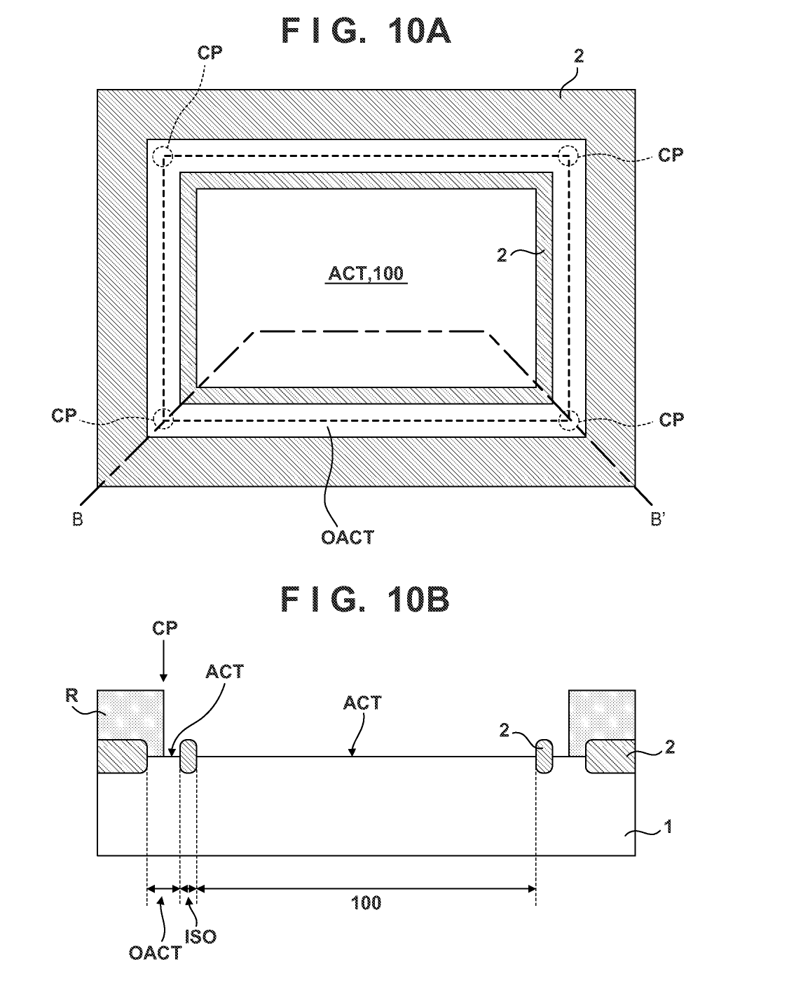

In the above-described embodiment, the corner portion CP of the resist pattern R1 is arranged, as illustrated in FIGS. 1B, 3A, and 3B, in the outermost active region MOA for the pixel arranged at the outermost portion in the pixel array region 100. FIGS. 10A and 10B show a modification of the above-described embodiment. FIG. 10A is a plan view and FIG. 10B is a sectional view taken along a B-B′ line in FIG. 10A. In an example shown in FIGS. 10A and 10B, the active region ACT includes an outer active region OACT arranged outside the pixel array region 100, and the corner portion CP is arranged in the outer active region OACT. The outer active region OACT is arranged to surround the pixel array region 100 over its entire circumference. No pixel element is arranged in the outer active region OACT.

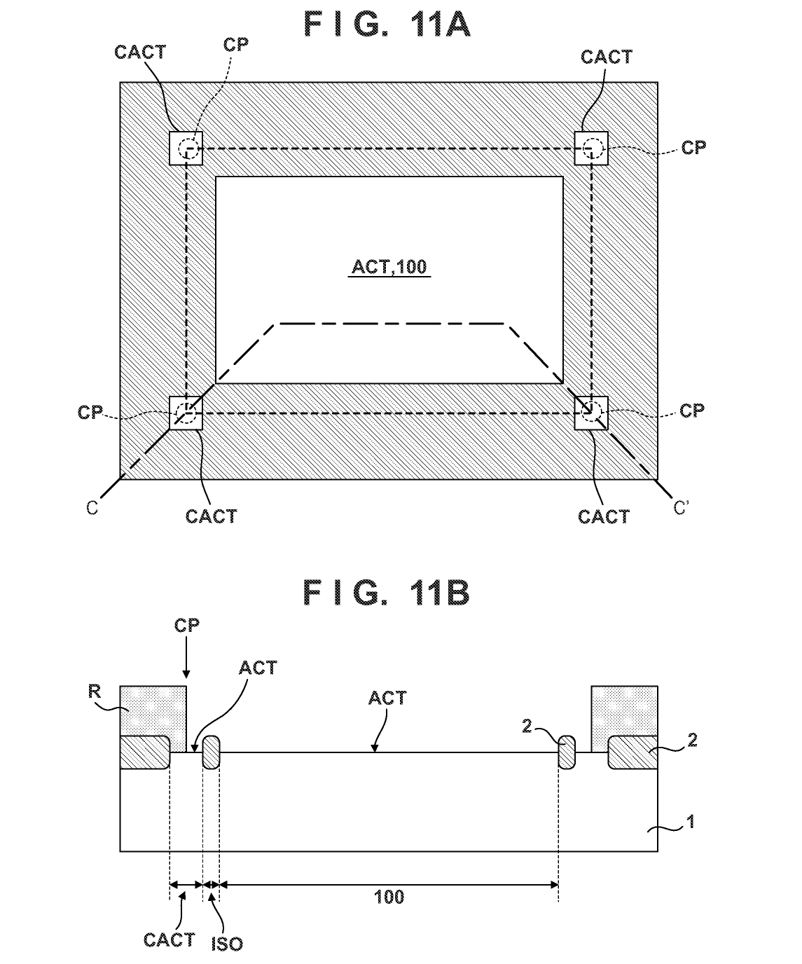

FIGS. 11A and 11B show another modification. FIG. 11A is a plan view and FIG. 11B is a sectional view taken along a C-C′ line in FIG. 11A. In an example shown in FIGS. 11A and 11B, the active region ACT includes four active regions CACT arranged outside the four corners of the pixel array region 100 respectively, and the corner portions CP are arranged in four active regions CACT.

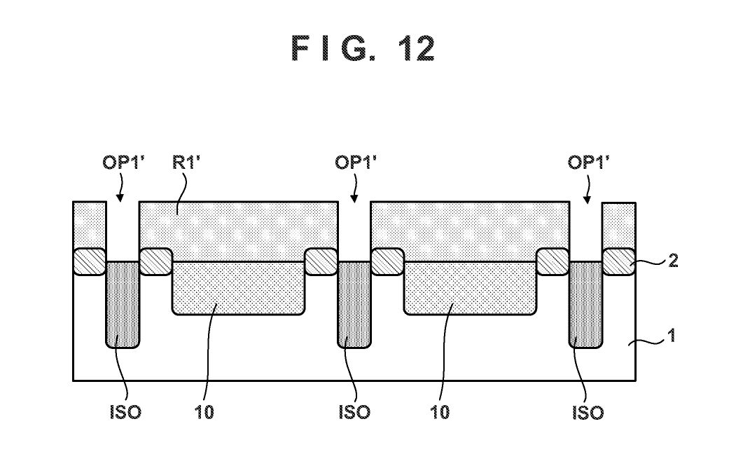

FIG. 12 shows still another modification. FIG. 12 illustrates a resist pattern R1′ having a plurality of openings OP1′ for one pixel array region 100. Such resist pattern R1′ is used to implant ions into regions isolated from each other within one pixel array region 100 at, for example, an ultrahigh energy of 6 MeV. The plurality of openings OP1′ can be used to form semiconductor regions ISO which isolate the plurality of pixels forming the pixel array region 100 from each other.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-001953, filed Jan. 8, 2014, which is hereby incorporated by reference herein in its entirety.

What is claimed is:

1. A method of manufacturing a solid-state image sensor, comprising steps of:
forming a resist film with a thickness of not less than 7 μm on a semiconductor substrate including an active region and an element isolation region;
forming a resist pattern including an opening by performing a photolithography process on the resist film; and
implanting ions into a pixel array region on the semiconductor substrate through the opening,
wherein the opening of the resist pattern includes a corner portion, and the corner portion is positioned not above the element isolation region but above the active region.

2. The method according to claim 1, wherein the active region includes an outermost active region for, out of a plurality of pixels forming the pixel array region, a pixel arranged at an outermost portion in the pixel array region, and
the corner portion is arranged in the outermost active region.

3. The method according to claim 1, wherein the active region includes an outer active region arranged outside the pixel array region, and
the corner portion is arranged in the outer active region.

4. The method according to claim 3, wherein the outer active region is arranged to surround an entire circumference of the pixel array region.

5. The method according to claim 3, wherein the outer active region includes four active regions arranged outside four corners of the pixel array region respectively, and
the corner portions are arranged in the four active regions.

6. The method according to claim 1, wherein the opening is one common opening to the plurality of pixels which form the pixel array region.

7. The method according to claim 6, wherein in the implanting the ions, a first semiconductor region is formed in the semiconductor substrate,
the method further comprises steps of:
forming, by performing a photolithography process, a second resist pattern including a plurality of openings corresponding to the plurality of pixels respectively on the semiconductor substrate; and
forming a second semiconductor region by implanting ions of a conductivity type different from that for forming the first semiconductor region into the plurality of pixels through the plurality of openings of the second resist pattern, and
the second semiconductor region functions as a charge accumulation region and has a smaller maximum depth than the first semiconductor region.

8. The method according to claim 1, wherein the resist pattern has the plurality of openings.

9. The method according to claim 8, wherein in the implanting the ions, a semiconductor region configured to isolate a plurality of pixels forming the pixel array region from each other is formed.

10. A method of manufacturing a solid-state image sensor, comprising steps of:
forming, on a semiconductor substrate on which a pixel array region including a plurality of pixels and a peripheral region arranged outside the pixel array region are defined and which has an active region and an element isolation region, a resist pattern having one common opening to the plurality of pixels in the pixel array region, and
implanting ions into the plurality of pixels in the pixel array region on the semiconductor substrate through the opening,
wherein the opening of the resist pattern includes a corner portion, and the corner portion is positioned not above the element isolation region but above the active region.

11. The method according to claim 10, wherein the resist pattern includes a thickness of not less than 7 μm.

12. The method according to claim 11, wherein in the step of implanting the ions, a first semiconductor region is formed in the semiconductor substrate,
the method further comprises steps of:
forming, by photolithography, a second resist pattern having a plurality of openings corresponding to the plurality of pixels respectively on the semiconductor substrate; and
forming a second semiconductor region by implanting ions of a conductivity type different from that for forming the first semiconductor region into the plurality of pixels through the plurality of openings of the second resist pattern, and
the second semiconductor region functions as a charge accumulation region and has a smaller maximum depth than the first semiconductor region.

13. The method according to claim 10, wherein the active region includes an outermost active region for, out of a plurality of pixels forming the pixel array region, a pixel arranged at an outermost portion in the pixel array region, and
the corner portion is arranged in the outermost active region.

14. The method according to claim 10, wherein the active region includes an outer active region arranged outside the pixel array region, and
the corner portion is arranged in the outer active region.

15. The method according to claim 14, wherein the outer active region is arranged to surround an entire circumference of the pixel array region.

16. The method according to claim 14, wherein the outer active region includes four active regions arranged outside four corners of the pixel array region respectively, and
the corner portions are arranged in the four active regions.
